(19) United States
(12) Patent Application Publication
(10) Pub. No.: US 2008/0087975 A1
(43) Pub. Date: Apr. 17, 2008

(54) Chip package and chip packaging method

(75) Inventors: Chia-Shuai Chang, Tao-Yuan Hsien (TW); Cheng-Lung Chuang, Tao-Yuan Hsien (TW); Chia-Ming Wu, Chung-Li Industrial Park (TW)

Correspondence Address: BACON & THOMAS, PLLC, 625 SLATERS LANE, FOURTH FLOOR, ALEXANDRIA, VA, 22314, US

(73) Assignee: IMPAC Technology Co., Ltd., Tao-Yuan Hsien (TW)

(21) Appl. No.: 11/581,444

(22) Filed: Oct. 17, 2006

(51) Int. Cl. H01L 31/0203; H01L 21/00

(52) U.S. Cl. 257/433; 438/64; 257/E31.117

(57) ABSTRACT

A chip package and a chip packaging method for use in optical applications are disclosed. The packaging method includes the steps of: a) providing a substrate having a first surface and a second surface; b) bonding first passive devices on the first surface; c) adhering a first chip to the first surface; d) forming a protection cover over the first surface for covering the first passive devices and the first chip; e) bonding second passive devices on the second surface; f) adhering a second chip to the second surface; g) providing a lid assembly having a frame with an opening window and pillars for contacting with the second surface; h) laminating the lid assembly on the second passive devices and the second chip such that gaps are formed between the frame and edges of the second surface; and i) filling a filler into the gaps to seal the second passive devices and the second chip in the lid assembly.

### FIELD OF THE INVENTION

The present invention relates to a semiconductor package, and more particularly, to a chip package and a chip packaging method for use in optical applications.

### BACKGROUND OF THE INVENTION

Semiconductor chips have input/output pads that must be connected to external circuitry in order to function as part of an electronic system. The connection media is typically an array of metallic leads or a support circuit, although the connection can be made directly to a circuit panel. Several connection techniques are widely used. Meanwhile, chip scale packages (CSPs) have emerged as a popular packaging technique for memory chips such as static random access memory (SRAM), dynamic random access memory (DRAM) and flash memory as well as other chips with low pin counts. Chip scale packages are hardly larger than the chip itself. However, advanced logic chips such as microprocessors, digital signal processors (DSPs) and application-specific integrated circuits (ASICs) often require the package to be considerably larger than the chip to accommodate high pin counts and meet motherboard pitch limitations.

Furthermore, as demands for higher IC operation speeds with smaller dimensions increases, it becomes a trend to integrate as many functions as possible into a single chip, i.e., system on chip (SOC), or to integrate several chips with different functions into a single package, such as, system in package (SIP). When integrating the functions of analog, memory, and logic functions into one single chip, there are some unsolved integration issues. Therefore, a multi-chip stacked package is disclosed.

Refer to FIGS. 1(A)- 1(E). They illustrate a method of packaging a multi-chip module for a camera according to the prior art. At first, a substrate 11 is provided as shown in FIG. 1(A). A first package 12, such as a DSP of BGA, is displaced on the substrate 11; and a plurality of surface mount technology (SMT) passive devices 13 are also displaced on the same surface of the substrate 11, as shown in FIG. 1(B). Furthermore, an imaging chip 14 is adhered on the same surface of the substrate 11, wherein the imaging chip 14 is conductive by means of wire bonding, as shown in FIG. 1(C). After packaging the imaging chip 14 and a plurality of SMT passive devices 13 to form a second package 15, as shown in FIG. 1(D), a lens module 16 is further disposed on the second package 15. Certainly, a flexible board 17, as shown in FIG. 1(E), will be soldered with the substrate 11 for providing a camera.

As known, the package technology keeps on miniaturizing day by day in accordance with several applications in light of heat dissipation through dense array packages. However, the prior art discloses a multi-chip module with two chip packages disposed on the same surface of the substrate. For minimization, the substrate 11 should be utilized efficiently. If several chips of different packages should occupy the entire surface of the substrate 11, the entire surface of the substrate should be reduced. Therefore, the remaining surface of the substrate 11 for a plurality of passive devices and the chip is limited, thereby being disadvantageous for minimization. Hence, the compatibility between the multi-chip module and several packages should be considered. The invention disclosed herein fulfills this need.

Although chip package for use in optical applications are technically feasible, in practice they are very difficult to implement. The packages discussed above perform very well but are disadvantageous to utilize the entire surface for minimization. Furthermore, the packages are too expensive and tend to limit cost reduction efforts due to their high cost material and labor content. What is needed is a simple packaging approach that is low cost, easily assembled, and reliable. Therefore, it needs to provide a chip package and a method thereof for use in optical applications, which introduces two packages disposed on top and bottom surfaces of the substrate for being good at utilizing packaging space and facilitating to minimization, and can rectify those drawbacks of the prior art and solve the above problems.

### SUMMARY OF THE INVENTION

This paragraph extracts and compiles some features of the present invention; other features will be disclosed in the follow-up paragraph. It is intended to cover various modifications and similar arrangements included within the spirit and scope of the appended claims, and this paragraph also is considered to refer.

Accordingly, the prior art is limited by the above problems. It is an object of the present invention to provide a chip packaging method for use in optical applications, which introduces two packages disposed on top and bottom surfaces of the substrate for being good at utilizing packaging space and facilitating to minimization, and can rectify those drawbacks of the prior art and solve the above problems.

In accordance with an aspect of the present invention, the chip packaging method for use in optical applications, includes the steps of: a) providing a substrate having a first surface and a second surface; b) bonding a plurality of first passive devices on the first surface of the substrate; c) adhering a first chip to the first surface of the substrate; d) forming a protection cover over the first surface of the substrate for covering the plurality of first passive devices and the first chip; e) bonding a plurality of second passive devices on the second surface of the substrate; f) adhering a second chip to the second surface of the substrate; g) providing a lid assembly having a frame with an opening window and a plurality of pillars for contacting with the second surface of the substrate; h) laminating the lid assembly on the plurality of second passive devices and the second chip such that a plurality of gaps are formed between the frame and edges of the second surface; and i) filling a filler into the plurality of gaps to seal the plurality of second passive devices and the second chip in the lid assembly for obtaining an entire sealed package.

Preferably, the substrate includes a ceramic substrate and a PCB.

Preferably, the first chip and the second chip are both bonded on the substrate through a plurality of wires.

Preferably, the step b) and step e) are executed by means of surface mounting technology (SMT).

Preferably, the plurality of pillars are disposed at corners of the frame.

Preferably, the filler is an epoxy resin.

Preferably, the lid assembly further comprises a glass piece disposed on the opening window.

Preferably, the first chip is a digital signal processor (DSP).

Preferably, the second chip is an imaging chip.

It is an object of the present invention to provide a chip package for use in optical applications, which introduces two packages disposed on top and bottom surfaces of the substrate for being good at utilizing packaging space and facilitating to minimization, and can rectify those drawbacks of the prior art and solve the above problems.

In accordance with an aspect of the present invention, the chip package for use in optical applications, includes a substrate having a first surface and a second surface; a plurality of first passive devices and a first chip disposed on the first surface; a protection cover disposed over the first surface of the substrate for covering the plurality of first passive devices and the first chip; a plurality of second passive devices and a second chip disposed on the second surface; a lid assembly having a frame with an opening window and a plurality of pillars, wherein the plurality of pillars contacts with edges of the second surface of the substrate to form a plurality of gaps around edges of the substrate; a glass piece disposed in the opening widow to cover the substrate; and a filler filled into the plurality of gaps around edges of the substrate to obtain an entire sealed package.

Preferably, the substrate includes a ceramic substrate and a PCB.

Preferably, the first chip and the second chip are both bonded on the substrate through a plurality of wires.

Preferably, the plurality of first passive devices and the second passive devices are disposed on the substrate by means of surface mounting technology (SMT).

Preferably, the filler is an epoxy resin.

Preferably, the plurality of pillars are disposed at corners of the lid assembly.

Preferably, the first chip is a digital signal processor (DSP).

Preferably, the second chip is an imaging chip.

The above objects and advantages of the present invention will become more readily apparent to those ordinarily skilled in the art after reviewing the following detailed description and accompanying drawings, in which:

### BRIEF DESCRIPTION OF THE DRAWING

FIGS. 1(A)-1(E) illustrate a method of packaging a multi-chip module for a camera according to the prior art; and

FIGS. 2(A)-2(K) illustrate a chip packaging method for use in optical applications according to the present invention.

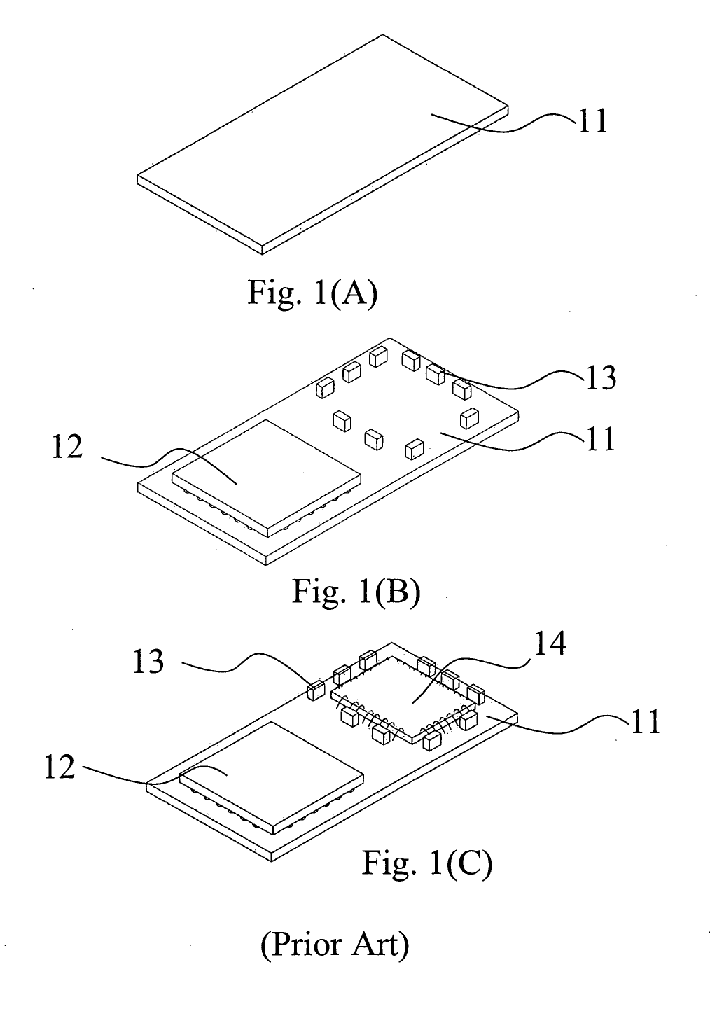

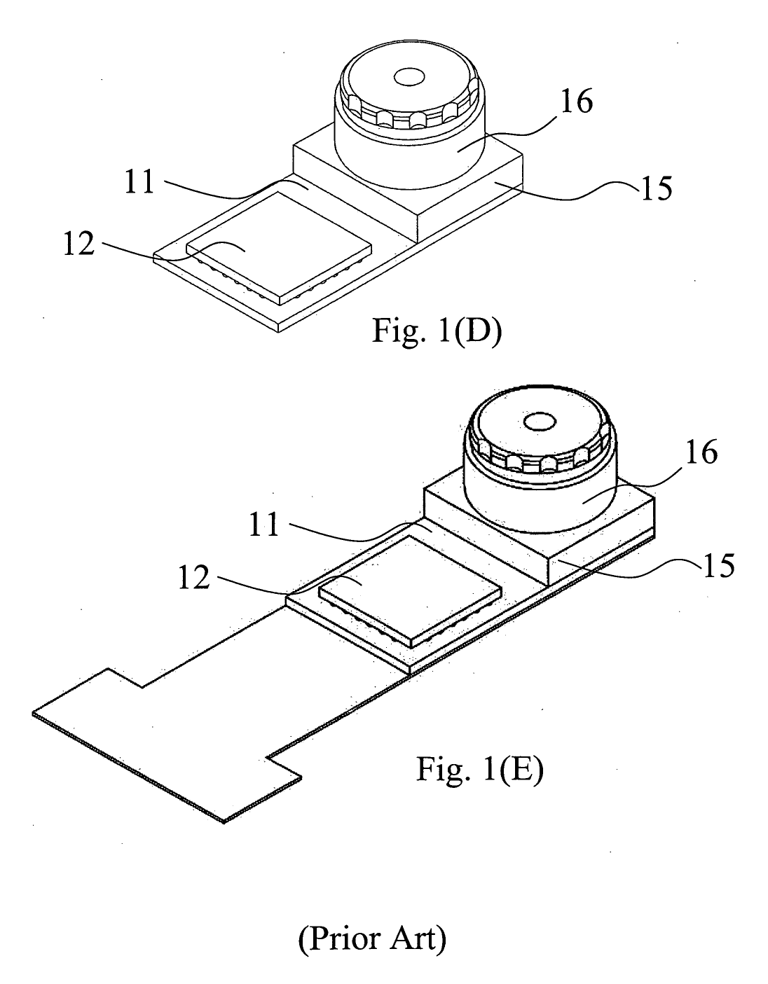

### DETAILED DESCRIPTION OF THE PREFERRED EMBODIMENTS

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

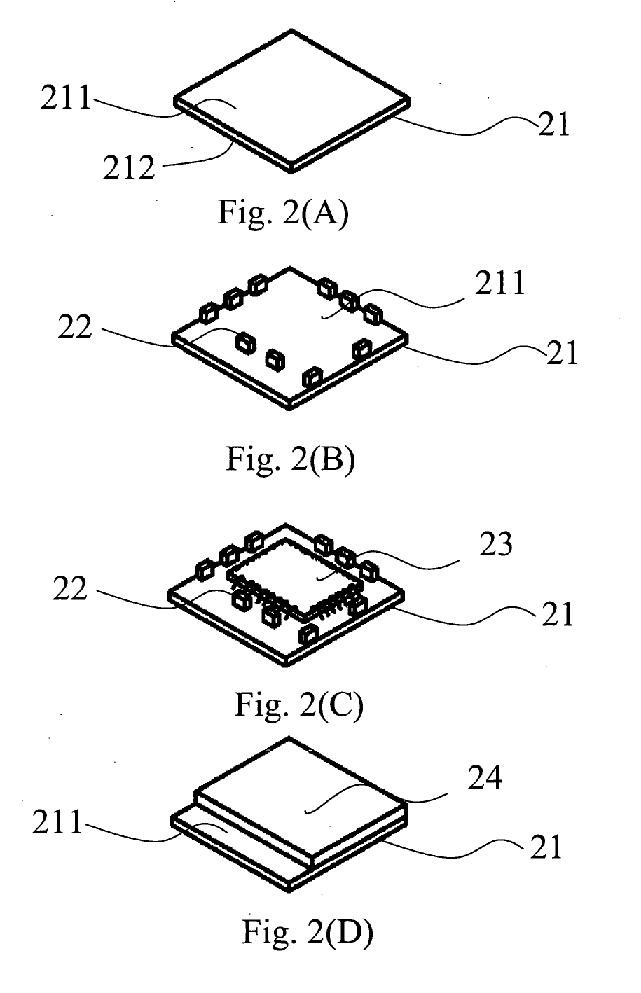

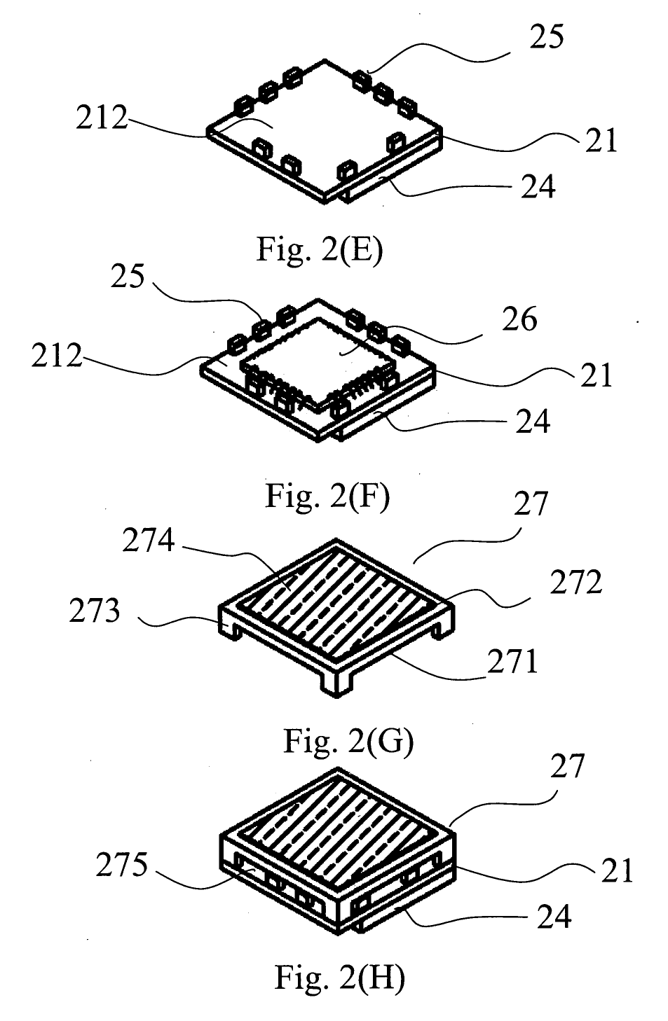

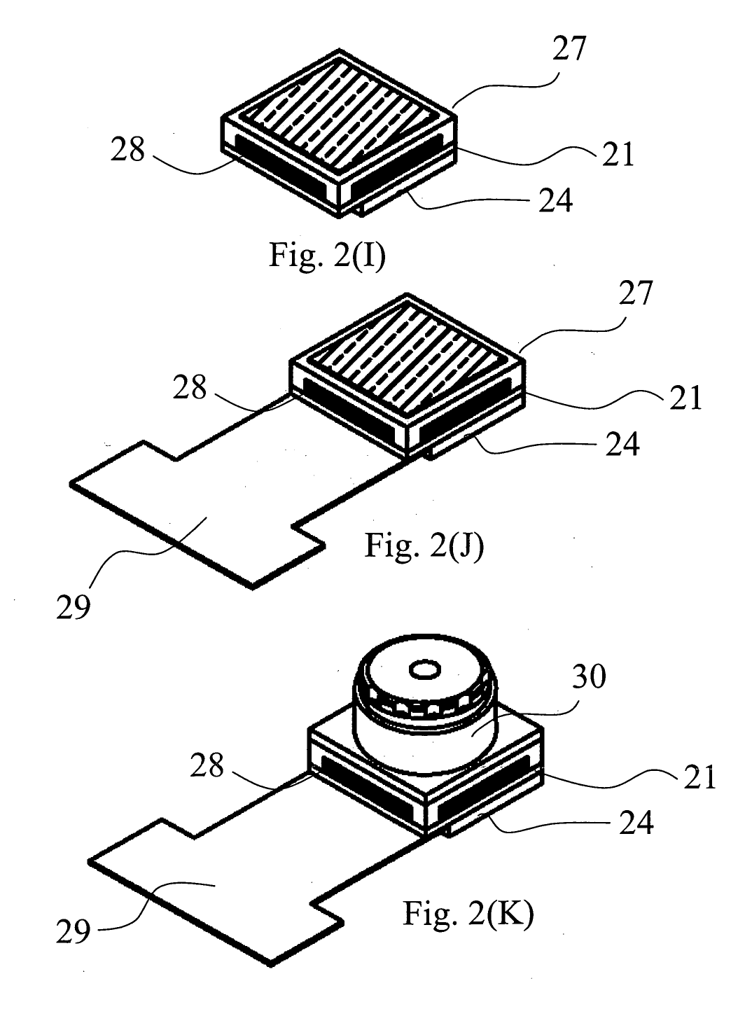

Please refer to FIGS. 2(A)-2(K). They illustrate a chip packaging method for use in optical applications according to the present invention. As shown in Figs, the chip packaging method for use in optical applications, includes the steps of: a) providing a substrate 21 having a first surface 211 and a second surface 212, as shown in FIG. 2(A); b) bonding a plurality of first passive devices 22 on the first surface 211 of the substrate 21, as shown in FIG. 2(B); c) adhering a first chip 23 to the first surface 211 of the substrate 21, as shown in FIG. 2(C); d) forming a protection cover 24 over the first surface 211 of the substrate 21 for covering the plurality of first passive devices 22 and the first chip 23, as shown in FIG. 2(D); e) bonding a plurality of second passive devices 25 on the second surface 212 of the substrate 21, as shown in FIG. 2(E); f) adhering a second chip 26 to the second surface 212 of the substrate 21; g) providing a lid assembly 27 having a frame 271 with an opening window 272 and a plurality of pillars 273 for contacting with the second surface 212 of the substrate 21, as shown in FIG. 2(F), wherein the plurality of pillars 273 are disposed at corners of the frame 271 and the lid assembly 27 further includes a glass piece 274 disposed on the opening window 272 to form the lid assembly 27; h) laminating the lid assembly 27 on the plurality of second passive devices 25 and the second chip 26, as shown in FIG. 2(H) (combining the structure of FIG. 2(F) and that of FIG. 2(G)) such that a plurality of gaps 275 are formed between the frame 271 and edges of the second surface 212 of the substrate 21; and i) filling a filler 28 into the plurality of gaps 275 to seal the plurality of second passive devices 25 and the second chip 26 in the lid assembly 27 for obtaining an entire sealed package, as shown in FIG. 2(I).

In practice, the chip packaging method could be performed for manufacturing optical applications of a camera. After obtaining the entire sealed package as shown in FIG. 2(I), the chip packaging method further includes the steps of: j) soldering a flexible board 29 on the substrate 21; and k) disposing a lens module 30 on the entire sealed package for the optical applications. Certainly, the first chip 23 and the second chip 26 can be bonded on the substrate 21 through a plurality of wires (not shown). On the other hand, the plurality of first passive devices 22 and the plurality of second passive device 25 are disposed on the substrate 21 by means of surface mounting technology (SMT). Preferably, the substrate 21 of the present invention can be a ceramic substrate or a PCB. Moreover, the filler 28 is made from an epoxy resin. Accordingly, the chip packaging method introduces two packages disposed on top and bottom surfaces of the substrate for being good at utilizing packaging space and facilitating to minimization.

According to the above method, the present invention also discloses a chip package. Referring to FIGS. 2(A)-2(K), the chip package for use in optical applications, includes a substrate 21 having a first surface 211 and a second surface 212; a plurality of first passive devices 22 and a first chip 23 disposed on the first surface 211; a protection cover 24 disposed over the first surface 211 of the substrate 21 for covering the plurality of first passive devices 22 and the first chip 23; a plurality of second passive devices 25 and a second chip 26 disposed on the second surface 212; a lid assembly 27 having a frame 271 with an opening window 272 and a plurality of pillars 273, wherein the plurality of pillars 273 are disposed at corners of the lid assembly 27 and contacts with edges of the second surface 212 of the substrate 21 to form a plurality of gaps 275 around edges of the substrate 21; a glass piece 274 disposed in the opening widow 272 to cover the substrate 21; and a filler 28 filled into the plurality of gaps 275 around edges of the substrate 21 to obtain an entire sealed package.

Similarly, the substrate 21 can be one of a ceramic substrate and a PCB. Meanwhile, the first chip 23 and the second chip 26 are both bonded on the substrate through a plurality of wires and, the plurality of first passive devices 22 and the second passive devices 25 are disposed on the substrate by means of surface mounting technology (SMT). Moreover, the filler 28 can be an epoxy resin. Due to the chip package could be performed for manufacturing optical applications of a camera, the chip package further includes a flexible board 29 soldering on the substrate 21; and a lens module 30 disposing on the entire sealed package for optical applications. Certainly, the first chip 23 can be a digital signal processor (DSP), and the second chip 26 can be an imaging chip. In this embodiment, the chip package introduces two packages disposed on top and bottom surfaces of the substrate, instead of occupying one surface of the substrate according to the prior art merely. Therefore, the chip package of the present invention has greater denseness for being good at utilizing packaging space and facilitating to minimization.

In conclusion, the present invention provides a chip package and a method thereof for use in optical applications, which introduces two packages disposed on top and bottom surfaces of the substrate for being good at utilizing packaging space and facilitating to minimization. Obviously, the surface of the substrate is utilized entirely according to the present invention; and the chip package of the present invention further introduces a lid assembly with four pillars combined with epoxy resin filler for facilitating to minimization, but the prior art fail to disclose that. Accordingly, the present invention possesses many outstanding characteristics, effectively improves upon the drawbacks associated with the prior art in practice and application, bears novelty, and adds to economical utility value. Therefore, the present invention exhibits a great industrial value.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A chip packaging method for use in optical applications, comprising the steps of:
a) providing a substrate having a first surface and a second surface;
b) bonding a plurality of first passive devices on said first surface;
c) adhering a first chip to said first surface;
d) forming a protection cover over said first surface for covering said plurality of first passive devices and said first chip;
e) bonding a plurality of second passive devices on said second surface;
f) adhering a second chip to said second surface;
g) providing a lid assembly having a frame with an opening window and a plurality of pillars for contacting with said second surface;
h) laminating said lid assembly on said plurality of second passive devices and said second chip such that a plurality of gaps are formed between said frame and edges of said second surface; and
i) filling a filler into said plurality of gaps to seal said plurality of second passive devices and said second chip in said lid assembly.

2. The chip packaging method according claim 1, wherein said substrate comprises a ceramic substrate and a PCB.

3. The chip packaging method according to claim 1, wherein said first chip and said second chip are both bonded on said substrate through a plurality of wires.

4. The chip packaging method according to claim 1, wherein said step b) and step e) are executed by means of surface mounting technology (SMT).

5. The chip packaging method according to claim 1, wherein said plurality of pillars are disposed at corners of said frame.

6. The chip packaging method according claim 1, wherein said filler is an epoxy resin.

7. The chip packaging method according claim 1, wherein said lid assembly further comprises a glass piece disposed on said opening window.

8. The chip packaging method according claim 1, wherein said first chip is a digital signal processor (DSP).

9. The chip packaging method according claim 1, wherein said second chip is an imaging chip.

10. A chip package for use in optical applications, comprising:
a substrate having a first surface and a second surface;
a plurality of first passive devices and a first chip disposed on said first surface;
a protection cover disposed over said first surface for covering said plurality of first passive devices and said first chip;
a plurality of second passive devices and a second chip disposed on said second surface;
a lid assembly having a frame with an opening window and a plurality of pillars, wherein said plurality of pillars contacts with edges of said second surface to form a plurality of gaps around said edges of said substrate;
a glass piece disposed in said opening widow to cover said substrate; and
a filler filled into said plurality of gaps around said edges of said substrate.

11. The chip package according claim 10, wherein said substrate comprises a ceramic substrate and a PCB.

12. The chip package according claim 10, wherein said first chip and said second chip are both bonded on said substrate through a plurality of wires.

13. The chip package according to claim 10, wherein said plurality of first passive devices and said second passive devices are disposed on said substrate by means of surface mounting technology (SMT).

14. The chip package according claim 10, wherein said filler is an epoxy resin.

15. The chip package according to claim 10, wherein said plurality of pillars are disposed at corners of said lid assembly.

16. The chip package according claim 10, wherein said first chip is a digital signal processor (DSP).

17. The chip package according claim 10, wherein said second chip is an imaging chip.
